(19) United States
(12) Patent Application Publication
(10) Pub. No.: US 2008/0217684 A1
(43) Pub. Date: Sep. 11, 2008

(54) Semiconductor device and manufacturing method thereof and power supply apparatus using the same

(75) Inventors: Takayuki Hashimoto, Tokai (JP); Takashi Hirao, Hitachi (JP); Masaki Shiraishi, Hitachinaka (JP)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Renesas Technology Corp., Tokyo (JP)

(21) Appl. No.: 12/011,286

(22) Filed: Jan. 25, 2008

(30) Foreign Application Priority Data
Mar. 5, 2007 (JP) 2007-054156

(51) Int. Cl. H01L 27/088; H01L 29/78; H01L 21/336

(52) U.S. Cl. 257/334; 257/330; 438/270; 257/E29.262; 257/E27.06; 257/E21.41

(57) ABSTRACT

A semiconductor device comprises a trench-gate type field-effect transistor on a semiconductor substrate having a first main surface and a second main surface oppositely positioned in a thickness direction, wherein the trench-gate type field-effect transistor comprises a first semiconductor region at the first main surface side; a second semiconductor region at the second main surface; a semiconductor well region between the first semiconductor region and the second semiconductor region; a trench formed so as to protrude in a first direction intersecting the second main surface; a gate electrode formed on an inner surface of the trench via a gate insulating film, and a bottom of the gate electrode is in the first semiconductor region, and a well bottom has a well deep portion and a well shallow portion, and the well deep portion is in a region more distant from the gate insulating film compared to the well shallow portion.

### CROSS-REFERENCE TO RELATED APPLICATION

The present application claims priority from Japanese Patent Application No. JP 2007-054156 filed on Mar. 5, 2007, the content of which is hereby incorporated by reference into this application.

### TECHNICAL FIELD OF THE INVENTION

The present invention relates to a semiconductor device and manufacturing method thereof and a power supply apparatus using the same, and particularly to a technique effectively applied to a semiconductor device comprising a trench-gate type field-effect transistor.

### BACKGROUND OF THE INVENTION

A power device, such as a so-called power transistor, like a field-effect transistor (FET) having high-voltage operation capable of coping with a large current, is widely applied to various applications for power control of industrial equipment and for power supply control of various electrical appliances.

As a high-voltage technique for a power transistor having a trench-gate structure, for example, Japanese Patent Application Laid-Open Publication No. 2005-524976 (Patent Document 1) and Japanese Patent Application Laid-Open Publication No. 2005-57050 (Patent Document 2) disclose techniques of performing impurity doping into a semiconductor region (well) at several times and forming a high-concentration well in order to form a channel under a gate oxide film.

As a high-voltage technique for a power transistor, for example, Japanese Patent Application Laid-Open Publication No. 8-264772 (Patent Document 3) discloses a technique for forming a well layer deeper than a trench gate.

### SUMMARY OF THE INVENTION

The present inventors have found that the following problems about achievement of the high-voltage power transistor according to the above-mentioned techniques occur by requiring fineness for high performance of a field effect transistor.

FIG. 2 shows a field-effect power transistor having a trench-gate structure, which the present inventors have considered. Reference numeral 1 denotes an n⁺-type silicon substrate, reference numeral 2 denotes an n⁻-type silicon region, reference numeral 3 denotes a p-type well, reference numeral 4 denotes a p⁺-type semiconductor region, reference numeral 5 denotes an n⁺-type semiconductor region, reference numeral 6 denotes a gate insulating film, reference numeral 7 denotes an insulating film, reference numeral 8 denotes a gate electrode, reference numeral 9 denotes a trench, reference numeral 11 denotes a source electrode, and reference numeral 12 denotes a drain electrode. In a state in which a voltage (drain voltage) is applied between the source electrode 11 and the drain electrode 12, an n-type inversion layer is formed in a region adjacent to the gate insulating film 6 in the p-type well 3 by increasing a voltage (gate voltage) to be applied to the gate electrode 8 of the trench structure, whereby the power transistor turns into the ON-state and a current flows with carriers moving from the source electrode 11 to the drain electrode 12 through the p-type well 3. Here, the gate voltage at which the inversion layer is formed in the p-type well 3 and the power transistor turns into the ON state is called a threshold voltage.

Since a low threshold voltage (about 1 to 2 V) is required for sufficiently driving a power transistor at the gate voltage of about 5 V, the concentration of impurities in the p-type well 3 is required to be as low as about 10¹⁷ cm⁻³. On the other hand, the depth of the p-type well 3 is required to be 1 to 2 μm in order to prevent punch-through of the p-type well 3 and realize an about 30 V high-voltage transistor.

The ON resistance R_{ds}(on) of the power transistor is expressed in the following equation.

R_{ds}(on)=R_{ch}+R_{acc}+R_{jfet}+R_{drift}+R_{sub}

where R_{ch} is a channel resistance, R_{acc} is an accumulation resistance, R_{jfet} is a JFET resistance, R_{drift} is a resistance of the n⁻-type silicon region 2, and R_{sub} is a resistance of the n⁺-type silicon substrate. Since the channel resistance R_{ch} is the largest, the p-type well 3 is made shallower (that is, the channel is made shorter) to reduce the channel resistance R_{ch}, and so the ON resistance R_{ds}(on) can be lowered.

However, there is a problem that if the p-type well 3 is made shallower, when a reverse voltage is applied, the p-type well 3 is punched through and so a leakage current increases. FIG. 3 is a graph where the horizontal axis represents a voltage applying in a reverse direction and the vertical axis represents a current. It can be understood from the graph that when the p-type well is shallow, a current increases at low voltages and punch-through is caused in the p-type well.

In the methods exemplified in the Patent Documents 1 and 2, techniques for increasing the concentration of the p-type well 3 without increasing a threshold voltage are proposed. However, the present inventors have found that a punch-through suppression effect is difficult to appear because the p-type well 3 has been gradually made shallower with demand for fine structures.

Also, in the technique exemplified in the Patent Document 3, a technique for suppression of the punch-through by pinch-off with neighboring p-type wells 3 is proposed. However, the present inventors have found that, with further demand for fine structures, the JFET resistance R_{jfet} becomes larger, so that the ON resistance R_{ds}(on) increases.

An object of the present invention is to provide a technique for reducing a channel resistance in a semiconductor device comprising a trench-gate type field-effect transistor.

The above-mentioned and other objects and novel features of the present invention will be apparent from the description of the present specification and the accompanying drawings.

Representative ones of inventions disclosed in the present application will be briefly described as follows.

A semiconductor device comprises a trench-gate type field-effect transistor on a semiconductor substrate having a first main surface and a second main surface oppositely positioned in a thickness direction, wherein the trench-gate type field-effect transistor comprises a first semiconductor region at the first main surface side; a second semiconductor region at the second main surface; a semiconductor well region between the first semiconductor region and the second semiconductor region; a trench formed so as to protrude in a first direction intersecting the second main surface; a gate electrode formed on an inner surface of the trench via a gate insulating film, and a bottom of the gate electrode is in the first semiconductor region, and a well bottom, as a junction between the semiconductor well region and the first semiconductor region, has a well deep portion and a well shallow portion, and the well deep portion is in a region more distant from the gate insulating film compared to the well shallow portion.

Effects obtained by the representative one among the inventions disclosed in the present application will be briefly described as follow.

In a semiconductor device comprising a trench-gate field-effect transistor, its channel resistance can be reduced.

### BRIEF DESCRIPTIONS OF THE DRAWINGS

FIG. 1 is a cross-sectional view of a principal part of a semiconductor device according to an embodiment of the present invention;

FIG. 2 is a cross-sectional view of a principal part of a semiconductor device considered by the present inventors;

FIG. 3 is a graph showing a relationship between a reverse direction voltage and a current in the semiconductor device considered by the present inventors;

FIG. 4 is a cross-sectional view of a principal part of the semiconductor device according to the embodiment of the present invention;

FIG. 5A is an explanatory diagram of an electric field distribution occurring in the semiconductor device considered by the present inventors and also a cross-sectional view of a principal part of the semiconductor device;

FIG. 5B is an explanatory diagram of an electric field distribution occurring in the semiconductor device according to the embodiment of the present invention and also a cross-sectional view of a principal part of the semiconductor device;

FIG. 6 is a graph where the ON resistance of the semiconductor device according to the embodiment of the present invention is compared with that of the semiconductor device considered by the present inventors;

FIG. 7 is a cross-sectional view of a principal part of the semiconductor device according to the embodiment of the present invention;

FIG. 8 is a graph showing a relationship between a ratio of a gate electrode protrusion distance to a gate electrode depth and a leakage current in the semiconductor device according to the embodiment of the present invention;

FIG. 9 is a graph showing a relationship between a ratio of a depth of a well deep portion to a gate electrode depth and a leakage current in the semiconductor device according to the embodiment of the present invention;

FIG. 10 is a cross-sectional view of a principal part of the semiconductor device according to the embodiment of the present invention;

FIG. 11A is a cross-sectional view of a principal part of the semiconductor device during the manufacturing steps according to the embodiment of the present invention;

FIG. 11B is a cross-sectional view of a principal part of the semiconductor device during the manufacturing steps according to the embodiment of the present invention;

FIG. 11C is a cross-sectional view of a principal part of the semiconductor device during the manufacturing steps according to the embodiment of the present invention;

FIG. 12A is a cross-sectional view of a principal part of the semiconductor device during the manufacturing steps continued from FIG. 11C;

FIG. 12B is a cross-sectional view of a principal part of the semiconductor device during the manufacturing steps continued from FIG. 12A;

FIG. 12C is a cross-sectional view of a principal part of the semiconductor device during the manufacturing steps continued from FIG. 12B;

FIG. 13A is a cross-sectional view of a principal part of the semiconductor device during other manufacturing steps continued from FIG. 11C;

FIG. 13B is a cross-sectional view of a principal part of the semiconductor device during other manufacturing steps continued from FIG. 13A;

FIG. 13C is a cross-sectional view of a principal part of the semiconductor device during other manufacturing steps continued from FIG. 13B; and

FIG. 14 is a circuit diagram of a power supply apparatus according to another embodiment of the present invention.

### DESCRIPTIONS OF THE PREFERRED EMBODIMENTS

Same reference numerals denote the same functional members throughout all the drawings for describing the present embodiments, and repetition of the descriptions thereof will be possibly omitted. Hereinafter, the embodiments according to the present invention will be described in detail with reference to the drawings.

### First Embodiment

In a first embodiment, a trench-gate type field-effect transistor with a low channel resistance will be exemplified.

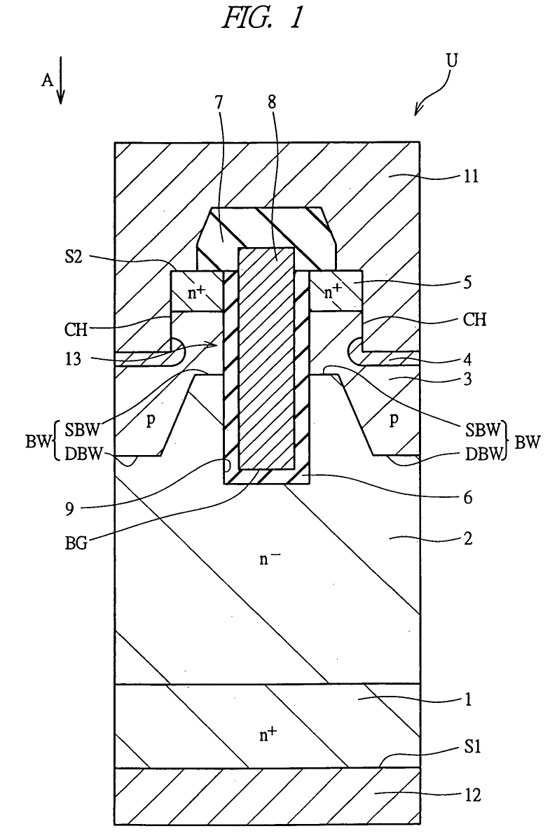

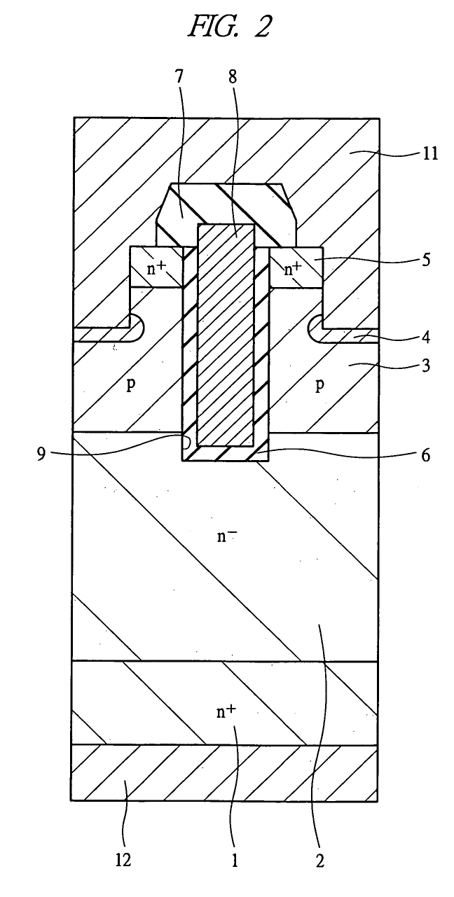

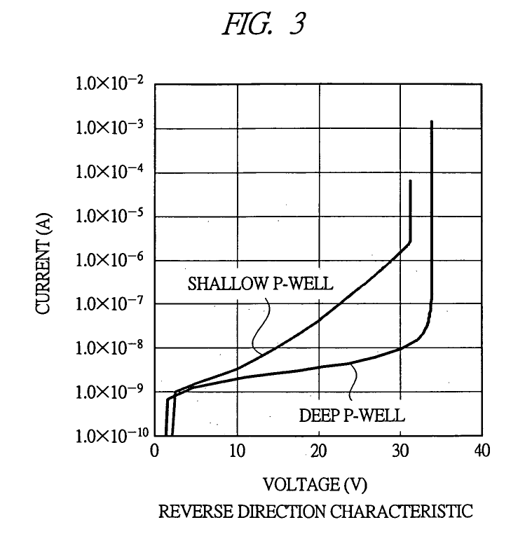

FIG. 1 is a cross-sectional view of a principal part of the trench-gate type field-effect transistor exemplified in the first embodiment. Reference numeral 1 denotes an n⁺-type silicon substrate (semiconductor substrate), reference numeral 2 denotes an n⁻-type silicon region (first semiconductor region), reference numeral 3 denotes a p-type well (semiconductor well region), reference numeral 4 denotes a p⁺-type semiconductor region, reference numeral 5 denotes an n⁺-type semiconductor region (second semiconductor region), reference numeral 6 denotes a gate oxide film (gate insulating film), reference numeral 7 denotes an insulating film, reference numeral 8 denotes a gate electrode, reference numeral 9 denotes a trench (trench portion), reference numeral 11 denotes a source electrode, and reference numeral 12 denotes a drain electrode.

Here, n-type (first conductivity type) represents a semiconductor in which its carriers are electrons and p-type (second conductivity type) represents a semiconductor in which its carriers are holes. “+” and “−” are subscripts indicating comparative carrier concentrations, and “+” means a higher concentration than that of “−”.

The n⁻-type silicon region 2 is formed on the surface of the n⁺-type silicon substrate 1 by epitaxial growth or other methods in advance. The p-type well 3, n⁺-type semiconductor region 5 and others are formed on the surface of the n⁻-type silicon region 2 by diffusion processes such as implantation of impurities and anneal. The manufacturing steps will be described in detail in later. Here, in the n⁺-type silicon substrate 1, a surface, which is not subjected to the diffusion steps and the drain electrode is finally formed thereon, is expressed as a first main surface S1. Also, another surface, which is positioned on the opposite side to the first main surface in the thickness direction and is subjected to the diffusion steps for formation of elements, is expressed as a second main surface S2. Further, the thickness direction of the n⁺-type silicon substrate, that is, the direction intersecting the second main surface S2 is expressed as a first direction A.

In the trench-gate type field-effect transistor described in the first embodiment, specifically, three main terminals of a drain, a source and a gate among the above-mentioned elements are configured as follows.

First, the n⁻-type silicon region 2 provided to the n⁺-type silicon substrate 1 at the first main surface S1 side constitutes a drain, and is connected to the drain electrode 12 via the adjacent n⁺-silicon substrate 1.

Next, the n⁺-type semiconductor region 5 provided to the n⁺-type silicon substrate 1 at the second main surface S2 side constitutes a source, and is connected to the source electrode 11.

Then, in the interior of the trench 9 formed in a state of extending from the second main surface S2 in the first direction A intersecting the second main surface S2 of the n⁺-type silicon substrate 1, the gate electrode 8 isolated via the gate oxide film 6 constitutes a gate.

In addition, the p-type well 3 provided between the n⁻-type silicon region 2 for a drain and the n⁺-type semiconductor region 5 for a source constitutes a well layer. That is, when a voltage is applied to the gate electrode 8, an electric field is generated in the p-type well 3 via the gate oxide film 6. The electric field intensity is particularly strong at a junction with the gate oxide film 6 in the p-type well 3 and n-type inversion occurs, so that carriers are generated. At this time, if a voltage is applied between the source electrode 11 and the drain electrode 12, carrier drift occurs through the n⁺-type semiconductor region 5 for a source and the n⁻-type silicon region 2 for a drain. Like the junction with the gate oxide film 6 in the p-type well 3 as above-mentioned manner, a region turned into the n-type inversion region by the gate voltage is called a channel region 13.

Also, the structure has a contact hole CH which is provided from the second main surface S2 of the n⁺-type silicon substrate 1 to the P-type well 3 so as to be integrally conductive with the source electrode 11 for electrically contact with the p-type well 3. At this time, the p⁺-type semiconductor region 4 is formed between the source electrode 11 and the p-type well 3 for ohmic contact.

The above structure is for a conventional trench-gate type field-effect transistor. In addition to the structure, the trench-gate type field-effect transistor according to the first embodiment has the following characteristics.

That is, the deepest portion of the gate electrode 8 in the first direction (the portion most distant from the second main surface) is expressed as a gate electrode bottom (bottom portion of the gate electrode) BG, and this gate electrode bottom BG is in the n⁻-type silicon region 2. Thus, the pinch-off effect between the gate electrode 8 and the p-type well 3 alleviates the electric field of the channel region 13, thereby suppressing the punch-through of the p-type well 3.

The pinch-off effect is such that, when applying a reverse direction voltage, depletion layers extending from the gate electrode bottom BG and from the p-type well 3 contact each other. With the effect, the electric field intensity increases in the region between the gate electrode bottom BG and the p-type well 3, thereby suppressing the increase in the electric field intensity inside the p-type well 3 including the channel region 13. In this manner, the electric field is alleviated in the p-type well 3 so that the punch-through is difficult to occur. Then, since there is no increase in the leakage current caused by the punch-through, the thickness of the p-type well 3 in the thickness direction of the n⁺-type silicon substrate 1 can be reduced, that is, the channel region 13 can be shortened. As a result, it is possible to manufacture the field effect transistor having the structure where the channel resistance R_{ch} is reduced by the shortened channel.

Further, in the trench-gate type field-effect transistor according to the first embodiment, there is exemplified the following structure where the pinch-off effect between the gate electrode bottom BG and the p-type well 3, which causes the lowered electric field of the channel region 13, can be more effectively caused.

In other words, when the junction between the p-type well 3 and the n⁻-type silicon region 2 is expressed as a well bottom BW, the well bottom BW has a well deep portion DBW with a comparatively long distance from the second main surface S2 of the semiconductor substrate 1 to the well bottom along the first direction A, and a well shallow portion SBW with a comparatively short distance therefrom, respectively. Also the well deep portion DBW is in a region more distant from the gate oxide film 6 compared to the well shallow portion SBW.

Thus, the gate electrode bottom BG protruding from the p-type well 3 and existing in the n⁻-type silicon region 2, and the well deep portion DBW are made closer in a region distant from the channel region 13. In this structure, the region with the strong electric field intensity due to the pinch-off is formed in the region distant from the channel region 13. As a result, the punch-through is more difficult to occur in the channel region 13, thereby more effectively reducing the leakage current.

Since the well deep portion DBW is in the region distant from the channel region 13, the depth thereof can be adjusted irrespective of the length of the channel region 13. In other words, even in the structure where the well deep portion DBW is provided to the well bottom BW, the well shallow portion SBW should serve as the channel region 13 and is not required to be made as deep as the well deep portion DBW (the channel region 13 is not required to be made longer). Therefore, according to the structure as described in the first embodiment, it is possible to independently obtain the effect of reducing the leakage current caused by the punch-through and the effect of reducing the channel resistance R_{ch} by the shortened channel, and to manufacture a field-effect transistor having both the effects.

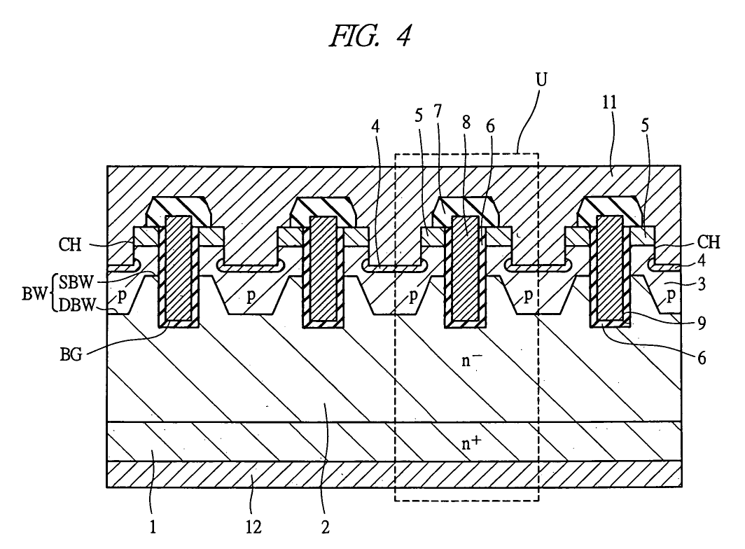

In the trench-gate structure field-effect transistor exemplified in the first embodiment, the structure described above and shown in FIG. 1 is a basic unit and called a unit cell. In practice, as the cross-sectional view shown in FIG. 4, a plurality of unit cells U is arranged as a repeatable basic unit.

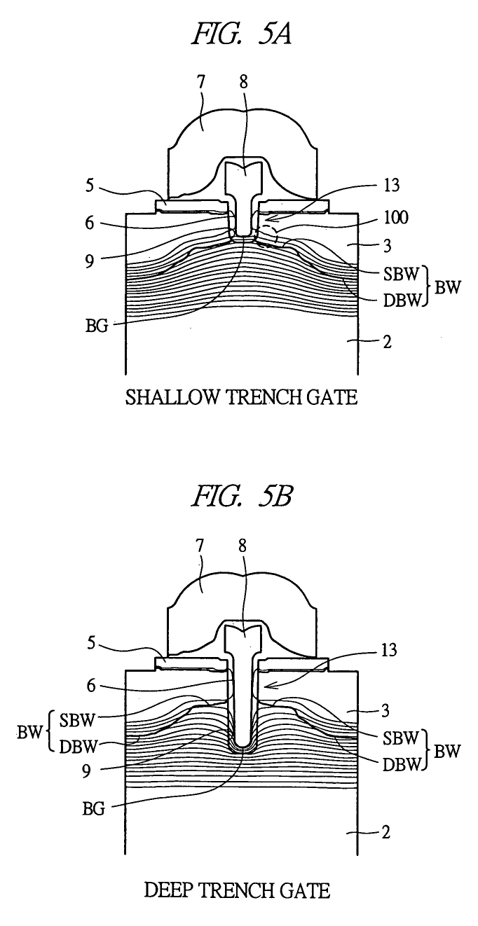

In the field-effect transistor having the structure exemplified in the first embodiment, the present inventors have examined the effect of the pinch-off by simulating the electric field distribution occurring around a field-effect transistor with the finite element method. In order to describe the result thereof, FIG. 5 shows the potential distribution occurring in the cross-section of the field-effect transistor.

FIG. 5A shows the result of the examination of the trench-gate type field-effect transistor in which the trench 9 does not protrude from the p-type well 3 (shallow trench gate) considered by the present inventors. From the indicated portion 100 in the figure, it can be found that equipotential lines of the potential penetrate inside the channel region 13, so that the electric field of the channel region 13 becomes strong.

FIG. 5B shows the result of the examination of the trench-gate type field-effect transistor in which the trench 9 protrudes from the p-type well 3 to the n⁻-type silicon region 2 (deep trench gate) shown in the first embodiment. It can be found that the penetration of the potential into the channel region 13 is weakened and the electric field of the channel region 13 is alleviated by the pinch-off effect caused between the gate electrode bottom BG and the well deep portion DBW. Consequently, the punch-through is difficult to occur in the channel region 13, and even if the channel region 13 is shortened, the leakage current can be suppressed.

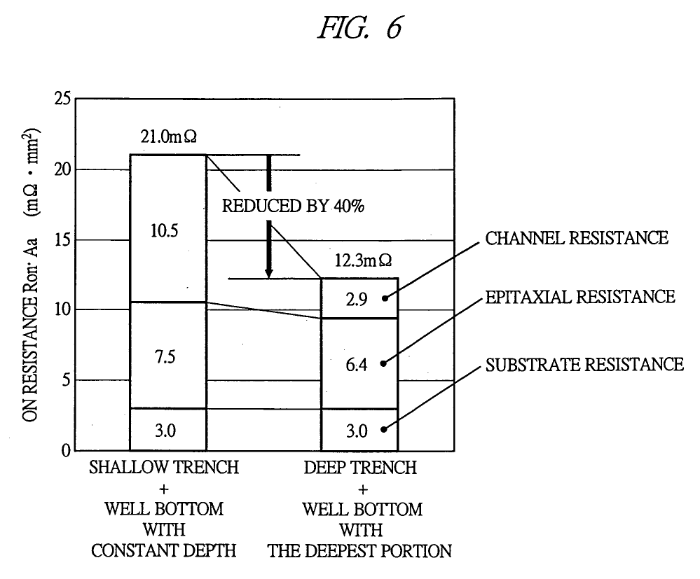

FIG. 6 shows the result of the measurement of the actual ON resistance of the field-effect transistor whose structure is exemplified in the first embodiment. For comparison, the result of the transistor in which the trench 9 does not protrude from the p-type well 3 and not have the well deep portion DBW, considered by the present inventors, is also shown. In FIG. 6, the result of the structure considered by the present inventors is shown at the left side, and the result of the field-effect transistor having the structure exemplified in the first embodiment is shown at the right side. The vertical axis represents a value obtained by multiplying a measured resistance value (mΩ) by a chip area (mm²) for expressing the normalized resistance value by the chip area.

The field-effect transistor exemplified in the first embodiment reduces the ON resistance by 40% as compared with the transistor having the structure considered by the present inventors. From the details of the resistance components, in the field-effect transistor shown in the first embodiment, the channel resistance R_{ch} is reduced from 10.5 mΩ·mm² to 2.9 mΩ·mm² by 72%. Therefore, it can be found that, when the channel region 13 is made shallower, the channel resistance R_{ch} is considerably reduced. This is because of the effect obtained by realizing the shortened channel with making the structure in which the leakage current can be suppressed with the reduction in the punch-through inside the p-type well 3.

Through the above description, there has been exemplified the trench-gate type filed-effect transistor having the structure where the gate electrode 8 protrudes from the p-type well 3 and the well bottom BW has the well shallow portion SBW and the well deep portion DBW. Also, the effect of suppression of the punch-through inside the p-type well 3 by causing the pinch-off outside the channel region 13 has been qualitatively explained. Further, the present inventors have more qualitatively examined the above-mentioned structure in which the pinch-off can be efficiently induced.

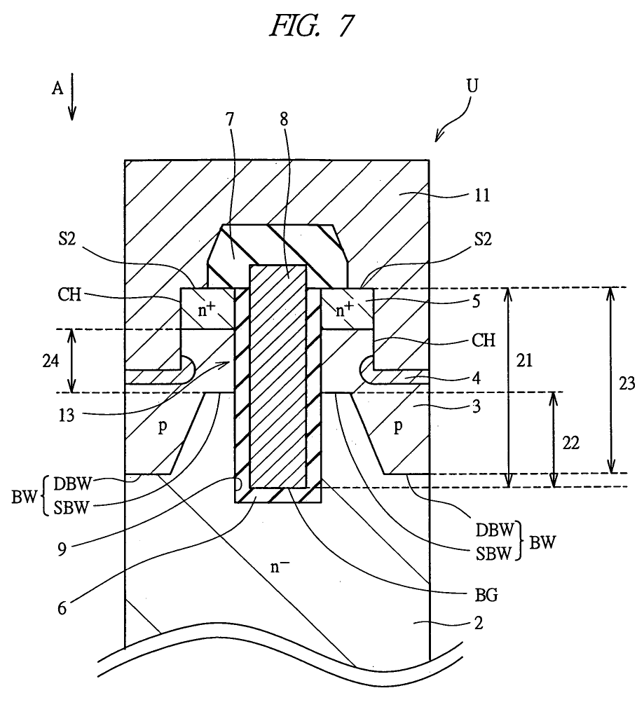

FIG. 7 shows standards for expressing dimensions of essential parts in the cross-sectional view of the field-effect transistor exemplified in the first embodiment.

At first, the length from the second main surface S2 as the surface of the n⁺-type semiconductor region 5 formed over the n⁺-type silicon substrate 1 to the gate electrode bottom BG is expressed as a gate electrode depth 21. Then, the length of a protruding portion of the gate electrode 8 into the n⁻-type silicon region 2 from the p-type well 3, along the first direction, is expressed as a gate electrode protrusion distance 22. Then, the length along the first direction from the second main surface S2 as the surface of the n⁺-type semiconductor region 5 formed over the n⁺-type silicon substrate 1 to the well deep portion DBW is expressed as a well deep portion depth 23.

Essentially, the gate electrode 8 is required for turning a portion adjacent to the gate oxide film 6 in the p-type well 3, that is, the channel region 13, into the n-type inversion, and is not required to reach the n⁻-type silicon region 2 for a drain. Particularly, in order to reduce the feedback capacity in the trench-gate type field-effect transistor, it is desirable that the gate electrode protrusion distance 22 is small. On the other hand, in the structure where the gate electrode 8 is recessed inside the p-type well 3, that is, the gate electrode protrusion distance 22 is made negative, a region where the inversion layer is not formed (so-called offset region) occurs in the channel region 13, so that the channel resistance R_{ch} considerably increases. Therefore, in the field-effect transistor having the structure considered by the present inventors, the gate electrode protrusion distance 22 is set to be about 10% of the gate electrode depth 21 so that the gate electrode protrusion distance 22 is as small as possible but is not negative distance, in consideration of variation in the manufacturing process.

On the contrary, in the first embodiment, the gate electrode protrusion distance 22 is set to be 20% or more of the gate electrode depth 21. This structure is for effectively generating the pinch-off between the gate electrode 8 and the p-type well 3 based on the following reasons. The point that the gate electrode 8 is positively protruded from the p-type well 3 is based on a novel concept different from the above-mentioned structure considered by the present inventors.

Here, there will be described the reason why it is desirable that the gate electrode protrusion distance 22 is set to be 20% or more of the gate electrode depth 21.

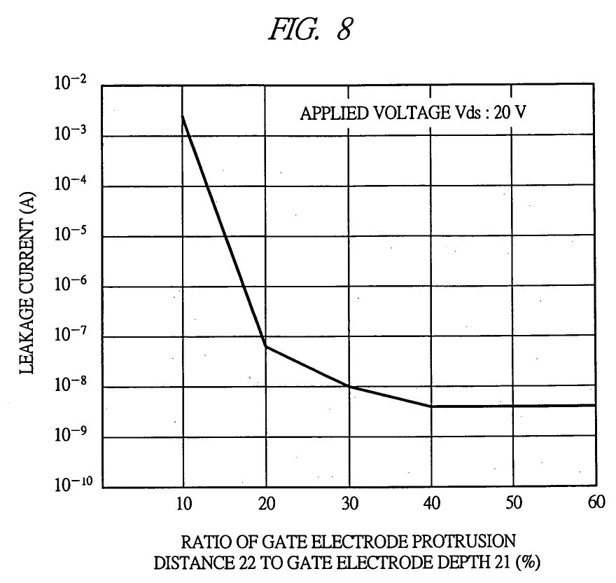

FIG. 8 illustrates the relationship between a ratio of the gate electrode protrusion distance 22 to the gate electrode depth 21 and a leakage current. It can be found that as the ratio of the gate electrode protrusion distance 22 to the gate electrode depth 21 increases, that is, as the gate electrode protrusion distance 22 is longer, the leakage current reduces. This is because of the effect in which the punch-through occurring inside the p-type well 3 is suppressed by the electric field of the p-type well 3 including the channel region 13 being alleviated by the pinch-off between the gate electrode 8 and the p-type well 3.

Further, it can be found that when the gate electrode protrusion distance 22 is below 20% of the gate electrode depth 21, the leakage current rapidly increases. This is because, in a case that the protrusion distance 22 of the gate electrode 8 from the p-type well 3 is below 20% of the gate electrode depth, when the drain voltage V_{ds} is applied between the source electrode 11 and the drain electrode 12 (for example, V_{ds}=20 V), depletion layers extending from the gate electrode bottom BG and from the p-type well 3 do not contact each other and so the pinch-off does not work.

As described above, in the trench-gate type field-effect transistor exemplified in the first embodiment, the gate electrode protrusion distance 22 from the p-type well 3 is set to be 20% or more of the gate electrode depth 21 so that the pinch-off is effectively generated to alleviate the electric field of the channel region 13, and the leakage current caused by the punch-through can be reduced.

Further, the present inventors have qualitatively examined the effect contributing to the pinch-off about the well deep portion depth 23 which is the distance from the second main surface S2 to the well deep portion DBW. Qualitatively, if the distance between the gate electrode bottom BG and the well deep portion DBW is too large, the pinch-off between the gate electrode 8 and the p-type well 3 is difficult to work. Then, the punch-through occurs in the channel region 13, so that the leakage current increases. From this viewpoint, the present inventors have found that the well deep portion depth 23 is set to be 80% or more of the gate electrode depth 21, whereby the pinch-off can be effectively generated between the gate electrode 8 and the well deep portion DBW. The reason therefor will be described below.

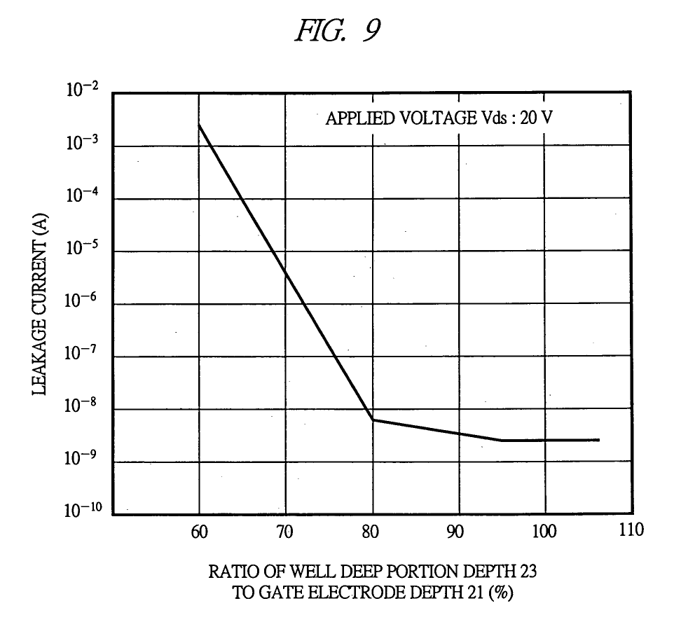

FIG. 9 illustrates the relationship between a ratio of the well deep portion depth 23 to the gate electrode depth 21 and a leakage current. It can be found that as the ratio of the well deep portion depth 23 to the gate electrode depth 21 increases, that is, as the well deep portion DBW is deeper, the leakage current reduces. This is because there is the effect in which the punch-through occurring inside the p-type well 3 is suppressed by the electric field of the p-type well 3 including the channel region 13 being alleviated by the pinch-off between the gate electrode 8 and the p-type well 3, as described above.

Further, it can be found that when the well deep portion depth 23 is below 80% of the gate electrode depth 21, the leakage current rapidly increases. This is because if the well deep portion depth 23 is below 80% of the gate electrode depth 21, when the drain voltage V_{ds} is applied between the source electrode 11 and the drain electrode 12 (for example, V_{ds}=20 V), depletion layers extending from the gate electrode bottom BG and from the p-type well 3 do not contact each other and so the pinch-off does not work.

As described above, in the trench-gate type field-effect transistor exemplified in the first embodiment, the well deep portion depth 23 is set to be 80% or more of the gate electrode depth 21 so that the pinch-off is effectively generated to alleviate the electric field of the channel region 13 and thus the leakage current caused by the punch-through can be reduced.

Next, there will be described the result of the examination, examined by the present inventors, for the length of the channel region 13 in the trench-gate type field-effect transistor exemplified in the first embodiment.

In the structure of the trench-gate type field-effect transistor considered by the present inventors, that is, the structure in which the gate electrode protrusion distance 22 is 10% or less of the gate electrode depth 21, or the well bottom BW of the p-type well 3 does not have the well deep portion DBW, the depth of the p-type well 3 is required to be about 1 to 2 μm in order to suppress the punch-through. This means that since the depth of the p-type well 3 is constant in this structure, the channel length is also restricted to about 1 to 2 μm. Therefore, the reduction in the channel resistance R_{ch} cannot be realized by further shortening a channel, which restricts the reduction in the ON resistance R_{ds}(on) of the transistor.

On the other hand, in the structure exemplified in the first embodiment, the suppression of the punch-through is realized by the gate electrode bottom BG protruding from the p-type well 3 and the well deep portion DBW, so that the channel region 13 can be made shallower, that is, the channel can be shortened. In practice, in the channel region 13 adjacent to the gate insulating film inside the p-type well 3 region, it is possible to make the channel length (distance 24 in FIG. 7) 1 μm or less, which is the distance from the boundary of the n⁻-type silicon region 2 to the boundary of the n⁺-type semiconductor region 5 for a source. Thus, the channel resistance R_{ch} can be considerably reduced.

Through the above descriptions, there has been described the dimension of the trench gate in the first direction A intersecting the first main surface S1 or second main surface S2, that is, in the depth direction of the trench gate, in the trench-gate type field-effect transistor exemplified in the first embodiment. On the other hand, the present inventors have also examined the dimension of the trench gate in the second direction B along the first main surface S1 or second main surface S2, namely, in the plan direction of the trench gate, and have found the following characteristics.

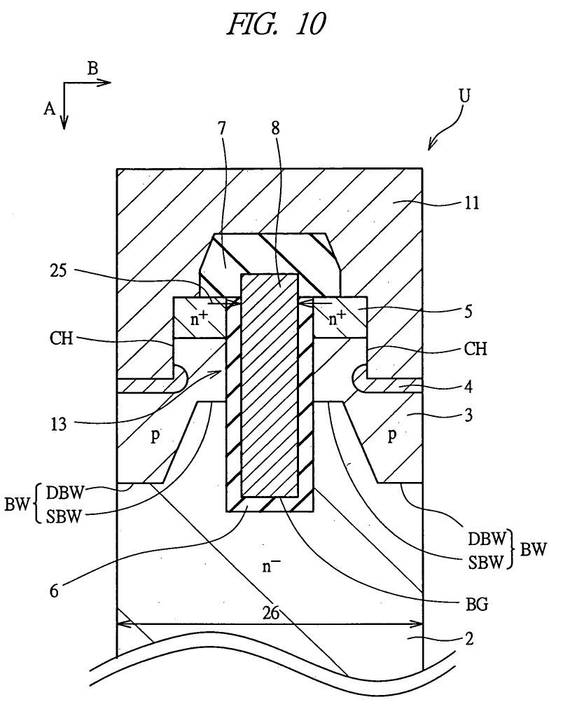

As shown in FIG. 10, reference numeral 25 denotes a width of the gate electrode 8 of the n⁺-type semiconductor region 5 (hereinafter, referred to as simply the gate width 25), and reference numeral 26 denotes a pitch of a unit cell U as a repeatable unit (hereinafter, referred to as simply the cell pitch 26). As described above, since the pinch-off is not effectively caused in the structure where the gate electrode bottom BG and the well deep portion DBW are separated too far, the electric field of the channel region 13 increases and the punch-through is easy to occur. In order to effectively cause the pinch-off between the gate electrode bottom BG and the well deep portion DBW, it is effective to make both closer to each other, and specifically it is desirable that the cell pitch 26 is as large as 20 times or less of the gate width 25.

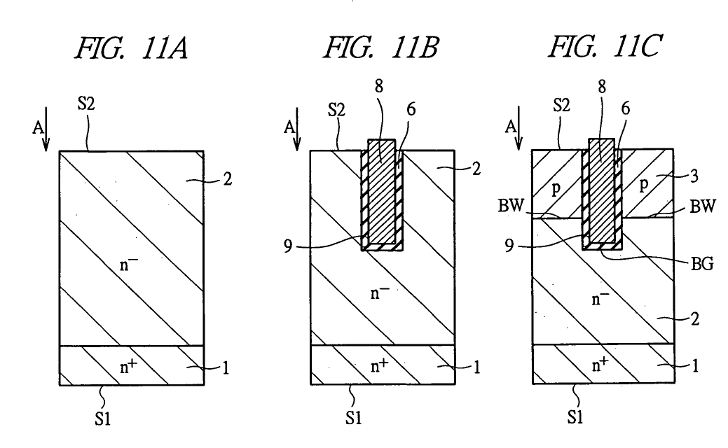

Next, the method of manufacturing the trench-gate type field-effect transistor exemplified in the first embodiment will be described in the order of steps with reference to FIGS. 11 to 13.

At first, as shown in FIG. 11A, the single crystal n⁻-type silicon region (first semiconductor region) 2 is deposited on the n⁺-type silicon substrate (semiconductor substrate) 1 by epitaxial growth. The n⁻-type silicon region 2 constitutes a drain of the field-effect transistor.

Here, a surface on which the epitaxial growth for the n⁻-type silicon is not performed and so the n⁺-type silicon substrate 1 is exposed is defined as the first main surface S1. Another surface on which the n⁻-type silicon region 2 is formed is defined as the second main surface S2. In this manner, the first main surface S1 and the second main surface S2 are oppositely positioned in the thickness direction.

Next, as shown in FIG. 11B, the trench (trench portion) 9 extending from the second main surface S2 is formed by dry etching or the like in the first direction A intersecting the second main surface S2. Thereafter, the gate oxide film (gate insulating film) 6 is formed on the inner surface of the trench 9. In the first embodiment, a silicon oxide film is formed as the gate oxide film 6 by, for example, thermal oxidation. Subsequently, the gate electrode 8 is formed so as to cover the gate oxide film 6 and fill the trench 9. In the first embodiment, polycrystalline silicon is formed as the gate electrode 8 by, for example, chemical vapor deposition or the like. Thereafter, the unnecessary polycrystalline silicon is removed by dry etching.

Subsequently, as shown in FIG. 11C, the p-type well (semiconductor well region) 3 is formed by implanting impurities as the p-type conductivity type from the second main surface S2. In the first embodiment, a group-III element such as boron (B), as impurities, is implanted by ion implementation in the first direction A, and a thermal treatment is performed.

At this time, the steps of introduction of the impurity is adjusted such that the well bottom BW which is the junction with the n⁻-type silicon region 2 in the p-type well 3 does not reach a deeper region than the gate electrode bottom (bottom portion of the gate electrode) BG. Thus, the structure in which the gate electrode bottom BG is in the n⁻-type silicon region 2, as exemplified in the first embodiment, can be formed.

Particularly, in the above-mentioned steps, the depth of the trench 9, the thickness of the gate oxide film 6, and the depth of the p-type well 3 are independently and arbitrarily adjusted, so that the trench-gate type field-effect transistor, in which the gate electrode protrusion distance 22 described by using FIG. 7 is 20% or more of the gate electrode depth 21, can be formed.

Here, as exemplified in the first embodiment, when there is configured such that the well bottom BW has the well deep portion DBW and the well shallow portion SBW, and also the well deep portion DBW is in a region more distant from the gate oxide film 6 compared to the well shallow portion SBW, the following steps are performed subsequent to the above steps.

At first, a photoresist film (protective film) is deposited on the second main surface S2 that the p-type well 3 is formed thereunder (not shown). Thereafter, the photoresist film is processed by photolithography such that the photoresist film covering exposed portions of the gate oxide film 6 and the gate electrode 8 and a part of the surface of the p-type well region adjacent thereto is integrally left. Then, the same impurity species as used in the step of forming the p-type well 3 are implanted from the second main surface S2 in the first direction A by ion implementation or the like by using the remaining photoresist film as a mask, and a thermal treatment is applied. Subsequently, the photoresist film is removed.

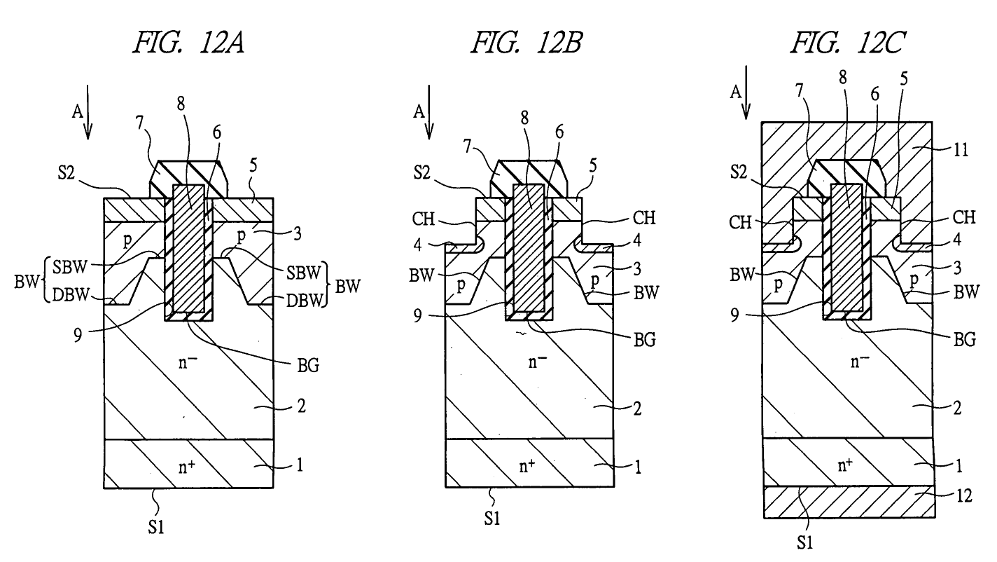

At this time, as shown in FIG. 12A, the impurities are introduced at a deeper region in the first direction A than the previously formed p-type well 3 by adjusting ion implementation energy and the thermal treatment conditions, whereby the well deep portion DBW is formed. Thus, the well bottom BW of the p-type well 3 can be configured to have the well shallow portion SBW in the region where the SBW joins with the gate oxide film 6, and the well deep portion DBW in the region distant from the former region.

Particularly, the trench-gate type field-effect transistor having a structure where the well deep portion depth 23 described by using FIG. 7 is 80% or more of the gate electrode depth 21 can be formed by arbitrarily adjusting the ion implementation energy and the thermal treatment conditions for forming the well deep portion DBW.

Thereafter, the n-type conductivity type impurities are introduced from the second main surface to form the n⁺-type semiconductor region (second semiconductor region) 5. In the first embodiment, a group-V element such as arsenic (As) or phosphorus (P), to be introduced as the impurities, is implemented by ion implementation or the like, and a thermal treatment is performed. The n⁻-type silicon region 2 constitutes a drain of the field-effect transistor.

Subsequently, the insulating film 7 is formed in order to insulate exposed portions of the gate insulating film 6 and the gate electrode 8 on the second main surface S2. As the process, for example, a silicon oxide film is deposited on the surface of the second main surface S2 by a CVD process, and a photolithography method or the like is applied so that a portion of the silicon oxide film covering the gate insulating film 6 and the gate electrode 8 is left.

Next, as shown in FIG. 12B, in order to contact with the p-type well 3, desired portions in the n⁺-type semiconductor region 5 and the p-type well 3 are removed by dry etching to form a contact hole CH. A photoresist film patterned by, for example, photolithography is used as an etching mask.

Subsequently, in order to realize an ohmic connection with a metal electrode formed later, the p⁺-type semiconductor region is formed at the bottom of the contact hole CH. Ion implantation or the like is used in the process.

Thereafter, as shown in FIG. 12C, the source electrode 11 is deposited at the side of the second main surface S2 and the drain electrode 12 is deposited at the side of the first main surface S1. In the first embodiment, a metal material mainly containing, for example, aluminum (Al) is deposited by a sputtering method.

Through the above-mentioned steps, the trench-gate type field-effect transistor exemplified in the first embodiment can be formed.

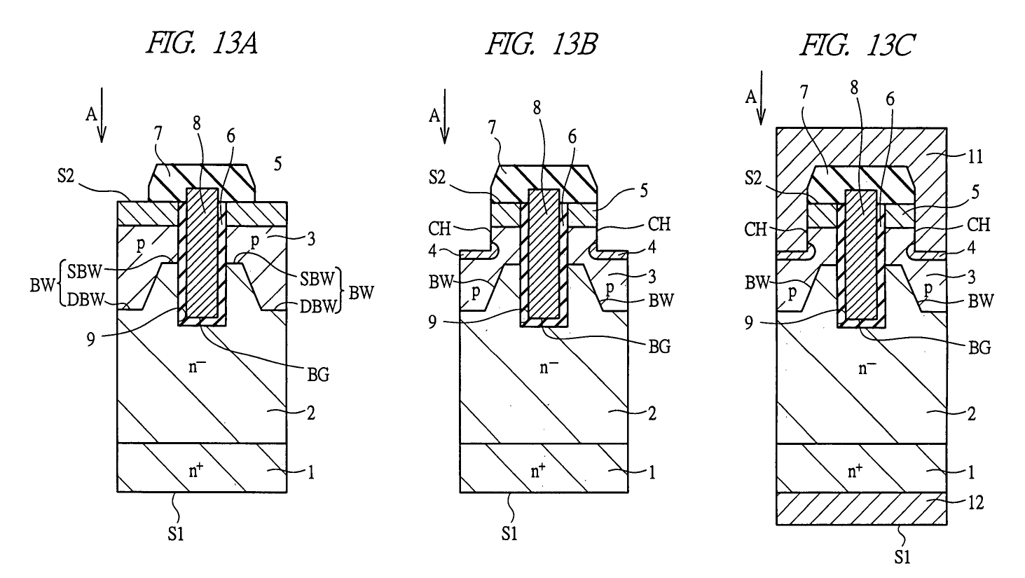

The steps described by using FIGS. 12A to 12C may be replaced with the steps described by using FIG. 13.

As shown in FIG. 13A, by the same manner as described in the above-mentioned FIGS. 11A to 11C, and FIG. 12A, the n⁻-type silicon region 2 for a drain on the n⁺-type silicon substrate 1, the trench 9, the gate oxide film 6, the gate electrode 8, the p-type well 3, the n⁺-type semiconductor region 5 for a source, and the insulating film 7 are formed.

Thereafter, as shown in FIG. 13B, dry etching is performed to the second main surface S2 using the insulating film 7 for gate insulation formed in the previous steps as an etching mask in the first direction A so that the contact hole CH for the p-type well 3 is formed. Subsequently, the p⁺-type semiconductor region 4 is formed at the bottom of the contact hole CH. In this case, the number of masks, which are used in a series of the photolithography steps of photoresist application, exposure and development, for forming the contact hole CH as the described method in the above-mentioned FIG. 12B, can be reduced, so that the costs can be reduced. Further, since the formation of the contact with the p-type well can be achieved in a self-alignment manner, the fine structure of cells can be realized.

Thereafter, by the same method as described in FIG. 12C, the source electrode 11 and the drain electrode 12 are formed as shown in FIG. 13C.

Through the above steps, the trench-gate type field-effect transistor exemplified in the first embodiment can be formed. In other words, the transistor has the structure in which the gate electrode 8 is intentionally protruded from the p-type well 3, the gate electrode bottom BG is formed in the n⁻-type silicon region and the p-type well 3 has the well bottom BW made of both the well shallow portion SBW joining with the gate insulating film 6 and the well deep portion DBW formed in a region distant from the junction.

As illustrated in the first embodiment, the pinch-off between the gate electrode bottom BG and the well deep portion DBW is generated in a region distant from the channel region 13 by making the trench-gate type field-effect transistor with the above-mentioned structure, thereby suppressing the punch-through in the channel region 13. As a result, since there is no increase in the leakage current caused by the punch-through, the channel region 13 can be made shallower, that is, the shortened channel in the field-effect transistor can be realized.

As the results mentioned above, it is possible to reduce the channel resistance in the trench-gate type field-effect transistor by the technique exemplified in the first embodiment.

### Second Embodiment

In a second embodiment, there will be described an example in which the field-effect power transistor having a low channel resistance exemplified in the first embodiment is applied to a power supply apparatus.

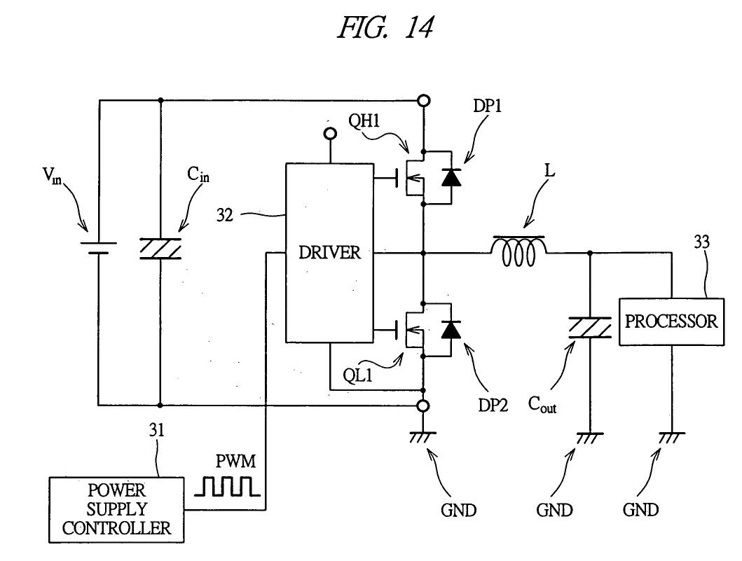

FIG. 14 shows a power supply circuit in the power supply apparatus of synchronous rectification system for supplying a power to a semiconductor device. In the second embodiment, for example, a processor is used as a semiconductor device to be supplied with a power. Vᵢₙ denotes a DC voltage source, GND denotes a ground potential, Cᵢₙ denotes an input capacity, QH1 denotes a high-side field-effect transistor (first field-effect transistor), QL1 denotes a low-side field-effect transistor (second field-effect transistor), DP1 denotes a diode incorporated in the high-side field-effect transistor QH1, DP2 denotes a diode incorporated in the low-side field-effect transistor QL1, L denotes an output inductor, Cut denotes an output capacity, 31 denotes a power supply controller, 32 denotes a driver and 33 denotes a processor as a power supply load.

The power supply apparatus having the above structure exemplified in the second embodiment is characterized in that it has the high-side field-effect transistor QH1 for rectification and/or the low-side field-effect transistor QL1 for commutation, and the trench-gate type field-effect transistor exemplified in the first embodiment is employed thereto.

The high-side field-effect transistor QH1 for rectification and the low-side field-effect transistor QL1 for commutation are turned ON/OFF alternately. Therefore, when the high-side field-effect transistor QH1 for rectification is in the ON state, the drain voltage of the low-side field-effect transistor QL1 for commutation in the OFF state has the DC source voltage Vᵢₙ. On the other hand, when the low-side field-effect transistor QL1 for commutation is in the ON state, the drain voltage of the high-side field-effect transistor QH1 for rectification in the OFF state has the ground potential GND.

Then, the drain voltage of the low-side field-effect transistor QL1 for commutation is smoothed by the output inductor L and the output capacity Cₒᵤₜ to become a DC voltage, so that a desired voltage is supplied to the processor 33.

In the field-effect transistor having the structure exemplified in the first embodiment, since the channel resistance R_{ch} thereof is reduced, the ON resistance is low. Therefore, in the second embodiment, when the field-effect transistor is employed to the high-side field-effect transistor QH1 for rectification and/or the low-side field-effect transistor QL1 for commutation, conductive loss caused by the resistance of the field effect transistor during a current passing can be reduced, thereby improving power supply efficiency.

Here, the field-effect transistor employed to the high-side field-effect transistor QH1 for rectification and/or the low-side field-effect transistor QL1 for commutation is the same as described in the first embodiment in detail and the description thereof will be omitted.

In the first embodiment, there has been exemplified the structure where the gate electrode 8 is positively protruded from the p-type well 3 and the structure having the well deep portion DBW in which the p-type well becomes deeper in a region distant from the channel region 13. In the above description, respective novel structures suppress the current leakage caused by the punch-through, and also are effective to reduce the channel resistance R_{ch} by shortening the channel. Therefore, even when a field-effect transistor having any structures exemplified in the first embodiment is used as the field-effect transistor used in the second embodiment, it is possible to obtain similar effects.

The invention made by the present inventors has been specifically described based on the embodiments. However, needless to say, the present invention is not limited to the above-mentioned embodiments and can be variously modified without departing from the scope thereof.

For example, although the field-effect transistor exemplified in the first and second embodiments is an n-channel transistor using the n-type inversion layer as a channel, when a p-channel transistor using a p-type inversion layer as a channel is used, it is possible to obtain similar effects. In this case, a desired structure can be formed in a manner that each denoted polarity in the embodiment is reversed.

The present invention can be applied to the semiconductor industry necessary for, for example, power control or power supply control in various industrial equipment and electrical appliances.

What is claimed is:

1. A semiconductor device comprising a trench-gate type field-effect transistor on a semiconductor substrate having a first main surface and a second main surface oppositely positioned in a thickness direction, the trench-gate type field-effect transistor comprising:
a first semiconductor region for a drain provided at a first main surface side of the semiconductor substrate and having a first conductivity type;
a second semiconductor region for a source provided at a second main surface side of the semiconductor substrate and having the first conductivity type;
a semiconductor well region provided between the first semiconductor region and the second semiconductor region and having a second conductivity type whose polarity of carrier is opposite to a polarity of the first conductivity type;
a trench formed so as to protrude from the second main surface in a first direction intersecting the second main surface of the semiconductor substrate;
a gate insulating film formed on an inner surface of the trench; and
a gate electrode formed so as to cover the gate insulating film and fill the trench,
wherein a bottom of the gate electrode is in the first semiconductor region.

2. The semiconductor device according to claim 1,
wherein a well bottom, as a junction between the semiconductor well region and the first semiconductor region, has a well deep portion with a comparatively long distance from the second main surface of the semiconductor substrate to the well bottom along the first direction, and a well shallow portion with a comparatively short distance therefrom, and
the well deep portion is in a region more distant from the gate insulating film compared to the well shallow portion.

3. The semiconductor device according to claim 2,
wherein a gate electrode protrusion distance being a length of a part of the gate electrode existing in the first semiconductor region along the first direction is 20% or more of a gate electrode depth being a distance from the second main surface of the semiconductor substrate to the bottom of the gate electrode.

4. The semiconductor device according to claim 2,
wherein, in the well bottom, a depth of the well deep portion being a distance from the second main surface of the semiconductor substrate to the well deep portion along the first direction is 80% or more of a gate electrode depth being a distance from the second main surface of the semiconductor substrate to the bottom of the gate electrode.

5. The semiconductor device according to claim 2,
wherein a channel length along the first direction in a channel region which is a junction with the gate insulating film in the semiconductor well region is 1 μm or less.

6. A method of manufacturing a semiconductor device comprising a trench-gate type field-effect transistor, comprising the steps of:
(a) preparing a semiconductor substrate having a first main surface and a second main surface oppositely positioned in a thickness direction, and a first semiconductor region with a first conductivity type;
(b) forming a trench protruding from the second main surface in a first direction intersecting the second main surface of the semiconductor substrate after the step (a);
(c) forming a gate insulating film on an inner surface of the trench after the step (b);
(d) forming a gate electrode so as to cover the gate insulating film and fill the trench after the step (c);
(e) forming a semiconductor well region by introducing impurities of a second conductivity type whose polarity of carrier is opposite to a polarity of the first conductivity type from the second main surface of the semiconductor substrate after the step (d); and
(f) forming a second semiconductor region by introducing impurities of the first conductivity type from the second main surface of the semiconductor substrate after the step (e),
wherein a bottom of the gate electrode is in the first semiconductor region, and
a gate electrode protrusion distance being a length of a part of the gate electrode existing in the first semiconductor region along the first direction is 20% or more of a gate electrode depth being a distance from the second main surface of the semiconductor substrate to the bottom of the gate electrode.

7. The method of manufacturing a semiconductor device according to claim 6,
wherein, after the step (e), a protective film is formed to integrally cover exposed portions of the gate insulating film and the gate electrode and a part of a surface of the semiconductor well region adjacent thereto within the second main surface of the semiconductor substrate,
then a well deep portion is formed by introducing impurities of the second conductivity type so as to reach a deeper region in the first direction than the semiconductor well region formed in the step (e), and thereafter, the step (f) is carried out, and
in the well deep portion, a depth of the well deep portion being a distance from the second main surface of the semiconductor substrate to a junction of the first semiconductor region along the first direction is 80% or more of the gate electrode depth.

8. A power supply apparatus of synchronous rectification type for supplying a power to a semiconductor device, the power supply apparatus comprising:
a first field-effect transistor; and
a second field-effect transistor,
wherein the first field effect transistor or the second field effect transistor is a trench-gate type field-effect transistor formed on a semiconductor substrate having a first main surface and a second main surface oppositely positioned in a thickness direction, and
the trench-gate type field-effect transistor comprises:
a first semiconductor region for a drain provided at a first main surface side of the semiconductor substrate and having a first conductivity type;
a second semiconductor region for a source provided at a second main surface side of the semiconductor substrate and having the first conductivity type;
a semiconductor well region provided between the first semiconductor region and the second semiconductor region and having a second conductivity type whose polarity of carrier is opposite to a polarity of the first conductivity type;
a trench formed so as to protrude from the second main surface in a first direction intersecting the second main surface of the semiconductor substrate;
a gate insulating film formed on an inner surface of the trench; and
a gate electrode formed so as to cover the gate insulating film and fill the trench,
wherein a bottom of the gate electrode is in the first semiconductor region, and
a gate electrode protrusion distance being a length of a part of the gate electrode existing in the first semiconductor region along the first direction is 20% or more of a gate electrode depth being a distance from the second main surface of the semiconductor substrate to the bottom of the gate electrode.

9. The power supply apparatus according to claim 8,
wherein a well bottom, as a junction between the semiconductor well region and the first semiconductor region, has a well deep portion with a comparatively long distance from the second main surface of the semiconductor substrate to the well bottom along the first direction and a well shallow portion with a comparatively short distance therefrom,
the well deep portion is in a region more distant from the gate insulating film compared to the well shallow portion, and,
in the well deep portion, a depth of the well deep portion being a distance from the second main surface of the semiconductor substrate to the well bottom along the first direction is 80% or more of the gate electrode depth.
